(19) United States
(12) Patent Application Publication
(10) Pub. No.: US 2003/0042918 A1
(43) Pub. Date: Mar. 6, 2003

(54) Receiver matrix configured to identify multiple external resistors

(76) Inventor: Peter Ar-Fu Lam, Torrance, CA (US)

Correspondence Address: Peter Ar-Fu Lam, 20104 Wayne Ave., Torrance, CA, 90503, US

(21) Appl. No.: 10/241,340

(22) Filed: Sep. 10, 2002

Related U.S. Application Data
(63) Continuation-in-part of application No. 10/208,346, filed on Jul. 30, 2002.
(63) Continuation-in-part of application No. 10/227,708, filed on Aug. 26, 2002.
(60) Provisional application No. 60/316,643, filed on Aug. 31, 2001.

(51) Int. Cl. G01R 27/08

(52) U.S. Cl. 324/711

(57) ABSTRACT

An electronics circuit designed for a matrix array of receivers configured to detect multiple external resistors of close values selected from the 100 ohm to 1 Mohm range, and to provide different responses according to the resistance of a resistor connected to a receiver.

This is a Continuation In Part application of pending U.S. patent application Ser. Nos. 10/208,346 filed Jul. 30, 2002 and 10/227,708 filed Aug. 26, 2002, which is the formal application of provisional patent application No. 60/316,643 filed Aug. 31, 2001.

### FIELD OF THE INVENTION

The present invention relates to an electronics circuit comprising an array of receivers, each configured to identify an external resistor so as to provide different responses according to the resistance value measured.

### BACKGROUND OF THE INVENTION

Traditional portable interactive learning toy for children provides a sensor pad positioned beneath a printed game card. The circuit of the sensor pad detects the position of a pen or by a finger by means of pressure, resistive, optical, capacitive or inductive changes. For many designs, the pen is required to be connected to the game console with a wire for the unit to receive the selection signal. The game play is defined by the pictorial content of the card designed according to an internal program or an external program represented by a game cartridge. This type of learning toy depends of “two dimensional” pictures illustrated on the pictorial card. The player is also required to make use of a pen or pressing with a finger to indicate the selected answer when a question is asked. According to a research of this invention, it was found that younger child likes to play with toys that are free to move around, rather than a pen connected with a wire or pressing hard with their tiny fingers. Pen is a tool that can only be handled by an older child. Besides, it was discovered that younger child tends to remember real life article than abstract expressions. In addition, younger child is more ready to learn from three-dimensional toys than to interpret the meanings of a two dimensional picture. It is the objective of this invention to provide an electronics circuit that enable a portable learning toy to replace the pen or finger pointing with real life three dimensional accessory toys free to move around. An embodiment of this electronics circuit makes use of the high resolution resistor recognition circuit that is capable to resolve resistor tolerance lower than 10%, preferably 5% as disclosed in applicants pending application Ser. No. 10/227,708 which is the formal application of provisional application No. 60/316,643. Another characteristics of the invention is that a multiple dimensional receiver array is provided to handle multiple external resistors to be received by the toy play set as disclosed in parent patent application Ser. No. 10/208,346 filed Jul. 30, 2002.

### SUMMARY OF THE INVENTION

The present invention is firstly directed to a hand held toy play set embodiment including a master toy unit and several groups of supporting or accessory toys. The master toy unit includes a power source; a processor; a program directing the processor to control the play pattern of the toy; an electrical to audio transducer such as a speaker to produce sound according to the play pattern; an array of receivers each provided with two contact terminals for interfacing with an external accessory toy article; a structure to receive an illustration card; a circuit to identify the card received; and possibly an array of push buttons for the child to select their choice of answer. Different groups of accessory toy articles are provided to support a game play. For example, multiple animal figures and a card illustrating a zoo are provided to support a game play teaching the child the knowledge of different animals. Another group of accessory toys is represented by a card illustrating a food store and a group of accessory toy members each represented by a 3D food article. Other accessory groups may be provided to teach children about more abstract concepts such as color, shape, numbers and alphabets.

An array of receivers is provided on a top-facing surface of the master toy unit. Each receiver is provided with two conductive contact terminals connected to the interfacing circuit located inside the master toy unit. The size of the receiver is to be carefully compromised. If the size of a receiver is too small, it will be difficult for a child to plug the accessory toy article onto the receiver. If the receiver size is too big, not much room will be left for providing illustration on the game card, which is to be placed on top of the receivers.

Illustrations on the game cards add color and fun to the game play. In the prior art embodiment, the game card is critical as it illustrates all the different choices of answers to be selected by the child. The child select an answer by pressing a pen or a finger down onto the two dimensional pictures illustrated on the card. Since the improved game pad enables the child to play with 3D accessory toys of real life shape, there is more freedom to design the illustrations and improve the play value of the toy set. For example, the game card can be printed with a short story, illustrated with words or pictures. Particular word location is replaced by a vacant space for the kid to fill in a proper accessory toy character. In this case, each of the vacant spaces of the card will be replaced by a hole adequate for an accessory toy member to make connection with the receiver located beneath the hole. It should be noted that the position of the hole should be properly aligned with the position of the receiver located beneath it. The theme of the card should be in line with the questions asked. For that reason, each game card is designated to work with a specific game program. Accordingly each card is provided an identifier for the processor to understand which card had been inserted into the master toy unit, and which game is to be played. Card identification can be provided by bar codes, magnetic strips or any other means that provides proper identification information to the processor.

Game programs may be stored inside the digital memory elements located inside the toy, or inside the game cartridges to be plugged into the master toy unit. External game cartridges enable the master toy unit to work with game to be launched at a later time. The digital memory elements, or memory means are represented by ROM (Read Only Memory), RAM (Random Access Memory), flash memory and any other type of digital data storage devices capable of providing digital data to the microcontroller of the master toy unit. The main function of the digital memory elements is to store the game program, the voice/melody messages required to support the game play and to control the circuit which identify the identification element of an external accessory toy.

Different groups of accessory toy members are required to support different game themes. Each toy member should be provided an identity circuit capable of interfacing to the processor through the metal contacts located inside the receiver. Typical identity circuit is represented by an integrated circuit, a resistor, or other working passive component to provide identity information. Applicant's pending U.S. patent application Ser. Nos. 09/896,434; 10/118,706 and 60/324,202 disclosed circuits enabling a portable master toy unit to power up an IC located inside an external accessory toy through the two conductive contacts, and to retrieve audio and digital information stored inside the IC. Alternately the accessory toy member can be identified by a resistor of specific value installed inside the accessory toy member. The concept of using a resistor for identification purpose and a circuit capable to identify less than ten different resistor values was firstly introduced by the applicant in an ARCO Once Upon A Time Playset designed for Mattel Toys during April 1994. Applicant's U.S. patent application Ser. No. 60/316,643 and it's formal patent application pending application Ser. No. 10/227,708 disclosed more advanced circuits and IC designs capable of recognizing over 90 high resolution resistor identities. Since the commodity resistors are provided with 5% tolerance, it is reasonable to provide a circuit that can resolve 10% resistor value resolution.

Using IC for identification purpose is relatively expensive. Using resistors or capacitors for identification purpose is a cheaper solution but the number of possible identifications is comparatively limited. Another solution resulted during the research of this invention is to provide each group of accessory toys with a specific shaped foot print, or a foot print having a special shaped lock key. The holes of the game card for playing with the specific accessory group is also formed with the same shape of foot print of that group, such that accessory characters from another group is not allowed to make contact with the receivers of the master toy unit. In this way, the same group of resistor values can be repeatedly used for other different groups of accessory toy figures. It is also a requirement for the contact design of the receivers to be universal and independent of the shape of the accessory toy footprint. A convenient design is a concentric female socket similar in nature to the sockets for most small electronics products to connect with the power adaptors. When connectors in other shapes are used, the orientation of the socket is to be carefully positioned to be in line with the orientation of the specified footprint. The identity of each accessory toy member represents a unique personality that enables the game program to determine if a correct answer has been provided by the player, or to produce a proper audio and/or visual response. Audio responses are provided by converting an audio signal stored inside the digital memory elements of the master toy unit, the game cartridge, or inside the IC located inside the accessory toy member. Visual responses can be achieved by providing power through the contacts terminals to a light bulb, LED or motor installed inside the main toy unit or an accessory toy member. As compared with the traditional prior art learning pads, the 3D learning pad disclosed enables the child to play with the individual accessory toy members, to feel it and to spend time and get more familiar with it. In addition, choice of answers from the 2D graphics printed on the game card is very limited for the traditional prior art learning pad, due to the size limitation of the game card. A manufacturer is now able to provide a much bigger number of accessory toy members for the child. It should be noted that when the game is targeted for the older kids, the 3D characters of the accessory toy members can be replaced by 2D photographs or pictures positioned on a podium structure of suitable footprint to reduce cost. From here it can be observed that the improved learning pad design provides more exciting audio/visual responses and incentives for the children to learn.

To add more complexity to the game play, an array of switches can be provided along the side of the game pad. These switches may be color coded, sign coded or letter coded for the child to enter an answer without using an accessory toy member. These switches are useful for selecting an answer not related with real life articles. Typical examples of these selections are taste such as sweet, bitter or sour; feeling such as happy, sleepy or anxious. When the switches are aligned in position with the receivers, special game plays can be designed allowing the child to interactively making use of both the accessory toy members and the side switches to play the game.

Once the target toy described above is identified, the next challenge is to provide electronics circuits that provide the required function. It is an objective of the subject invention to provide a multiple dimension array of receivers to minimize the number of pins required from the microcontroller and the resistor detection circuit. The circuit should be designed in a way to allow several resistors to be inserted into different receivers and stay in connection with the occupied receivers. It is also an objective of the subject invention to have every receiver be capable of resolving standard commercial resistor values of 5% tolerance. It is a further objective of the subject invention to have a “green” electronics circuit that consumes minimal operation power.

In order to conserve battery power, the resistor identification circuit and the microcontroller of the main toy unit should be kept at a low power standby mode, which consumes zero or negligible current, when the toy is not in use. As soon as an external resistor is received by any receiver, the main toy unit wakes up and transformed into a higher current active mode, starting a process to identify the value of the external resistor and then provides audio, visual and logical responses accordingly. If the toy is not played for a predetermined time, the internal program of the toy will turn the unit back into the low current standby mode.

In a first embodiment of the invention, two groups of I/O pins, or interface pins are provided by a microcontroller and arranged in a X and Y matrix format. By definition, an I/O or interface pin of a microcontroller includes but not limited to all different kinds of input sensing pins, output driving pins, programmable input and output pins, open drain or open source pins and pins capable of providing high impedance.

A first contact point connected to any of the X row of I/O pin and a second contact point connected any of the Y column of I/O pin is arranged to form a receiver. Accordingly, a matrix of “m” rows and “n” columns provides a total of “m×n” receivers. When a resistor is receive by a receiver connected to the number “i” I/O pin and the number “j” I/O pin, the circuit will wake up and transform from a low standby current mode into a higher current active mode to start measuring the resistance of the external resistor. The microcontroller then provides a preprogrammed response according to the resistance measured. For example, a 100 ohm resistor representing a frog of the toy set previously described will initiate the toy to produce a frog sound. A 270 kohm resistor represents a bird and a bird sound is generated. The responses produced are not limited to sounds, the microcontroller may turn on light bulb or LED to provide illuminated responses. It may provide graphic responses on display devices such as LCD display panel or TV screen. Alternately motion responses may be achieved by turning on a motor to provide animation effects.

As compared with A/D converter, a simpler method to identify the value of a resistor is obtained by measuring the charging or discharging characteristics of a capacitor in conjunction with a resistor. For the artisan skill in the art, the product of the values represented by a capacitor and a resistor forms a “RC” time constant. Given a known value of the capacitor and measure this time constant, the value of the resistor can be obtained. Accordingly a known capacitor is added to every column I/O pin of the circuit. The charging or discharging time of the RC pair is then measured to determine the unknown resistor value. In actual circuit design, it is not necessary for the full range of RC charging or discharging curve to be measured. In order to simplify the circuit design and save the cost of a voltage comparator circuit, the threshold voltage of an I/O pin can be used to determine the relative charging and discharging time of a RC circuit. Whenever a discharge timing is to be measured, the circuit needs to charge up the capacitor first. Therefore a rapid charging circuit, such as driving I/O pins is provided. An alternate method to charge up all the capacitors at one time is to provide a current source, either represented by a separated output pin, or represented by other current sourcing circuit such as a switched transistor. The current source is then connected to each of all the column pins. A diode is required between a single current source and multiple column capacitors to prevent the capacitors being shorted circuit by the current source.

Enlisted below are the standard commercial resistor values: Ohm range (discarding resistance value below 100 ohm): 100, 110, 120, 130, 150, 180, 200, 220, 240, 270, 300, 330, 360, 390, 430, 470, 510, 560, 620, 680, 750, 820, 910; total 24 different values. The k-ohm range is obtained by multiplying the above resistance values by 10 to provide another 24 different resistor values. The 10k-ohm range is obtained by multiplying the above range of resistor values by 100 to provide an additional resistor values. The 100k-ohm range resistor values is again obtained by multiplying the above resistor values by 1000 to provide further 24 resistor values. The total number of commercially available resistor values in between 100 ohm to 1M ohm is [(24×4)+1]=97. It means the high precision circuit provided by the subject invention is able to identify 97 different identity articles making use of a single commercial standard resistor in each article. If two resistors are provided in each article for identification detection (requires three to four contact points), the total number of combination is 97×97=9,409, which is more than enough for most applications. It should be noted that among the 97 resistor values identified, some of the resistor values are less popular and can be considered as a secondary standard resistor value. Examples of these values are 130 ohm, and 240 ohm. Since all these standard resistor values carry a 5% tolerance, it is essential to have a high precision circuit capable to resolve the roughly 10% value separation in between two adjacent resistor standard values. Since an upper margin resistor may have a value almost identical to the lower margin resistor of the next value, it may be required in the production process to sort out the marginal resistors so that their values will not overlap.

The tolerance of commercial capacitors is higher than that of the resistors. Typical value tolerance is 10% or higher for commodity capacitors. This tolerance may also vary from time to time due to chemical aging of the capacitor or poor temperature coefficient of the capacitor design. Therefore the reading circuit is preferred to be equipped with a calibration circuit. An example of the calibration circuit is to include a high tolerance resistor, say a 1% resistor of known value into the circuit. The microcontroller measures the time constant of the reference capacitors with this reference resistor to precisely determine the value of a reference capacitor before it starts to measure the value of an external resistor.

Another difficulty encountered during the invention process is that there are many different kinds of commercial capacitors, each carry different characteristics due to different structure and dielectric material used. As a result, the value span of each type of capacitor is very limited. For example, commercial ceramic capacitors provide capacitance range from nano farad to 0.2 micro farad. Commercial electrolytic capacitors provide a range from 0.1 micro farad to several thousand micro farad. The range of Tantalum capacitors is close to that of electrolytic capacitors but with a narrower range. It is beyond the resolution capability of the time measurement circuit of a microcontroller for a single capacitor to service the wide range of resistance values from 100 ohm to 1 Mohm. As a result, it is desirable to provide different type of capacitors in the same charging or discharging measurement circuit. That is to connect multiple capacitors to the column I/O pin as described above. In addition to the two dimensional switching circuit between the I/O pins of the X and Y array, a third dimension, or group of I/O pins is required to determine which capacitor is to be connected. If an external resistor failed to provide a reasonable reading with one capacitor, the third dimension I/O circuit will be switched to connect another capacitor for another round of charging or discharging time measurement. Depends on the circuit arrangement, a diode may also be connected in series with each capacitor to prevent the capacitance of one column to be coupled into another column.

Since each group of capacitors is able to service only a limited range of resistance values, every group of capacitors requires a different calibration resistance. Accordingly, reference resistors of different values are provided and a fourth dimension, or groups of switched I/O pins is required by the circuit to determine which reference resistor is to be turned on during the calibration process. Depends on the circuit arrangement, diodes may be connected in series with a reference resistor to prevent the calibration circuit to be short circuited.

Whenever an external resistor is received between a row pin and a column pin, a resistance is formed in between these two pins. If multiple resistors are received, the resistance reading between a row pin and a column pin will not truly represent the actual resistance of the external resistor because of the presence of other external resistors. Accordingly, a diode is required to be connected in series with every external resistor to provide a true reading.

According to another embodiment, a proprietary IC is designed to simplify the capacitor array of the RC circuit. Instead of providing different arrays of capacitors of the same value in the circuit, only one capacitor is provided to service each resistor range. Whenever the presence of an external resistor is detected, the proprietary microcontroller provides an internal switching circuit to the capacitor and carry out the RC measurement process. The number of calibration reference resistors is also reduced as a result.

Instead of using a RC charging and discharging circuit, other properly designed circuit can be utilized to service the two-dimensional receiver array if properly designed. Another circuit disclosed in the parent application can also be modified to measure resistance array formed in X and Y matrix format. An array of internal gates, each carries a different resistance value is connected in parallel or in series with the external resistor to form a potential divider. The value of the external resistor is then measured by measuring the voltage of this potential divider. Alternately an array of gated resistance is switched until the resulting voltage of the voltage divider hits a threshold voltage. A/D converter may also be utilized to measure the voltage formed by the voltage divider. In order to resolve the wide range of resistance values as previously discussed, multiple measurement circuits, each dedicated to a different range of resistance are provided. Arrays of switches are provided inside the microcontroller to connect the external resistor to the different measurement circuits. Internal array of switches may also be required to connect the different external reference resistors for calibrating these different measurement circuits.

It should be noted that all the resulted electronics circuits developed to supported the target toy is not limited to the application of the target toy described. It is the intention of this patent application to have the invented electronics circuit designed to service all other applications that are benefited from the novel features of the invented circuit design. The novel features of the invention are set forth with particularity in the appended claims. The invention will best be understood from the following description, when read in conjunction with the accompanying drawings.

### DESCRIPTION OF THE DRAWINGS

FIG. 1 illustrates the embodiment of a learning pad play set interacting with external 3D accessories each represented by a different resistor;

FIG. 2 illustrates an embodiment of the electronics circuit designed for the play set of FIG. 1;

FIG. 3 discloses the waveform to measure a resistor by a discharge curve;

FIG. 4 illustrated the change of discharge curve of FIG. 3 when a higher resistance is connected to the RC measurement circuit;

FIG. 5 is a circuit providing multiple groups of reference capacitors to service different ranges of external resistors;

FIG. 6 is an improvement of the circuit of FIG. 5 to provide calibration function;

FIG. 7 illustrates the condition when multiple external resistors are connected to the receiver arrays;

FIG. 8 illustrated improved design of the electronics circuit illustrated in FIG. 7;

FIG. 9 illustrates the arrangement of a proprietary integrated circuit requiring only one reference capacitor to service one range of external resistors and the simplified calibration circuit resulted; and

FIG. 10 illustrates alternate circuit design to measure multiple external resistors without using a RC measurement.

### DETAILED DESCRIPTION

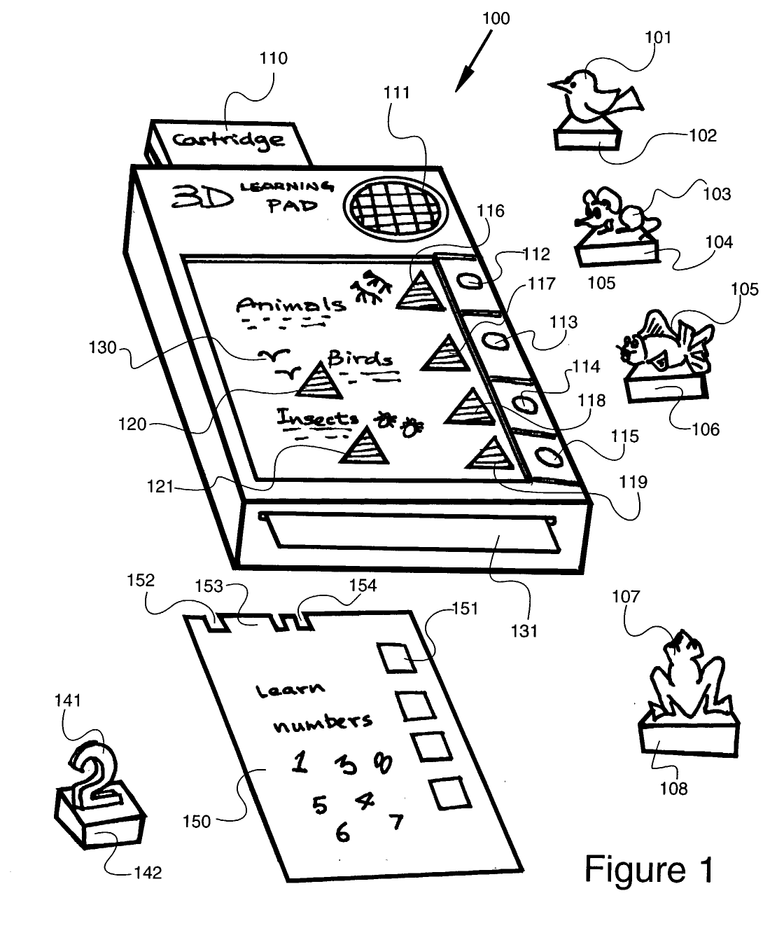

Attention is initially directed to FIG. 1, which depicts the combined application of a master toy embodiment 100 and multiple accessory toy members 101, 103, 105, 107 and 141. The master toy unit 100 comprises of a game cartridge 110; the speaker 111, a game card 131 and a line up of side switches 112 to 115. Inside the cartridge 110 are memory devices that stores a program to direct the game play. The game card 131 is provided with triangular holes 116 to 119 and 120, 121. Underneath these triangular holes are receivers structured to receive an external accessory toy member represented by the three dimension characters 101, 103, 105 and 107. Each of the receivers is provided with two contact terminals configured to make contact with the circuit of the accessory toy members when they are received by any of the receivers. An array of receivers are located at the panel beneath the game card 131. The game cards 131 and 150 are carefully designed such that the positions of each holes 116 to 119, 120, 121 and 151 is properly aligned with the location of a receiver. Inside each 3D accessory toy members is an identifier circuit, a voice generating circuit, a light bulb, a LED or a motor. In an example of a game play, the processor derived a message from the game cartridge and ask: “Find the mouse and place it on the first line!”. If the child picks the fish 105 for the receiver 116, another message will be announced to ask the child to try again. If the mouse 103 is selected for the receiver 116, the child is praised for the correct answer selected. Once the receivers 116 to 119 are correctly filled, the master toy unit may ask further question about the game play. A further example question is “Please select an animal that is able to fly!”. The correct answer is to select the button 113 by the side of the receiver 117 that accommodated the bird 101. It should be noted that all the accessory toy members 101, 103 105 and 107 belong to the same group that works with the game card 131. These accessory toy members are characterized by a triangular shape footprint. Game card 150 works with another group of 3D characters. Since the theme of the game card 150 is to learn numbers, all the accessory toy members are represented by 2D or 3D shapes of numbers exemplified by the toy member 141. It should be noted that the shape of the hole on the card 150 is designed to match with the foot print of the toy member 141. They are all of the same size square shape. In addition to the different shape of footprint required to identify the groups of accessory toy characters to be used, the master toy unit is designed to identify which game card was inserted. This can be achieved by providing an identifier to each of the game card, such as bar code and magnetic stripe. The slots 152, 154 and covered area 153 is designed for an optical or mechanical reader to detect the identity of the game card 150. Additional game cards and game cartridges may be provided to enrich game play. Different games should be supported with matched cartridge, game cards and the appropriate group of accessory characters.

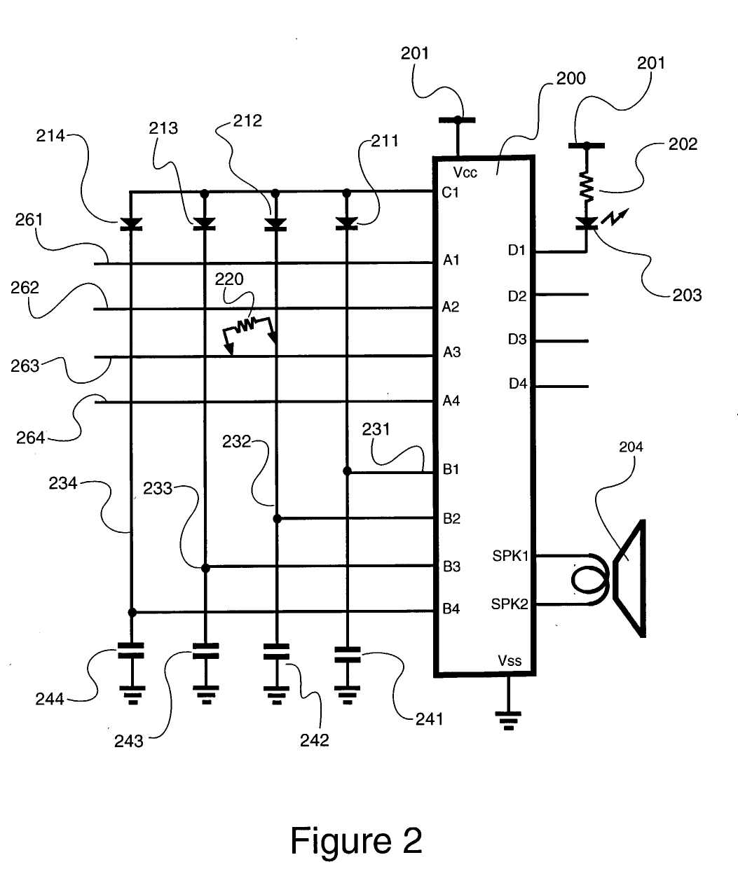

Attention is now directed to FIG. 2, which illustrates the circuit design to support the toy play set of FIG. 1. The microcontroller 200 provides a first group of I/O pins A1 to A4 to form the rows of a receiver matrix and a second group of I/O pins B1 to B4 to form the columns of the receiver matrix. An array of capacitors 241 to 244 are connected to each column pin of the circuit. A receiver is formed by two contact points, one connected to a row pin and the second one connected to a column pin. Accordingly the 4×4 matrix provides 16 receivers. The contact points of the receiver is configured to make contact with a resistor embedded inside an external article. For example, when an external bird shape article comprising the resistor 220 is connected across row A3 and column B2, the circuit measures the resistance of the resistor and initiates a proper response such as producing a song sing by a bird. As in the example of FIG. 1, when the microcontroller 200 detects a 100 ohm resistor representing the frog 107, it provides a response represented by a frog sound generated through the speaker 204. If a 560 kohm resistor representing the fish 106 is detected, the microcontroller 200 turns on the blue LED 203 which light up an aquarium shown on a play card. To identify the resistor 220, the microntroller firstly momentarily set the pin C1 to high, this action charge up the capacitor 242 through the diode 212. Then the B2 is set to input mode and pin A3 is set from high impedance to low. The capacitor will start to discharge through external diode 220. The signal obtained from pin B2 is monitored and the time required by the signal to turn from logic high to logic low is measured. The measured discharge timing is then compared with a predefined table, which directs the microcontroller to provide different responses according to the timing or resistance value identified. It should be noted that if the output current provide by the pin C1 is limited, the pin C1 can be connected to turn on a higher power current source such as a transistor current driver to speed up the initial charge up time.

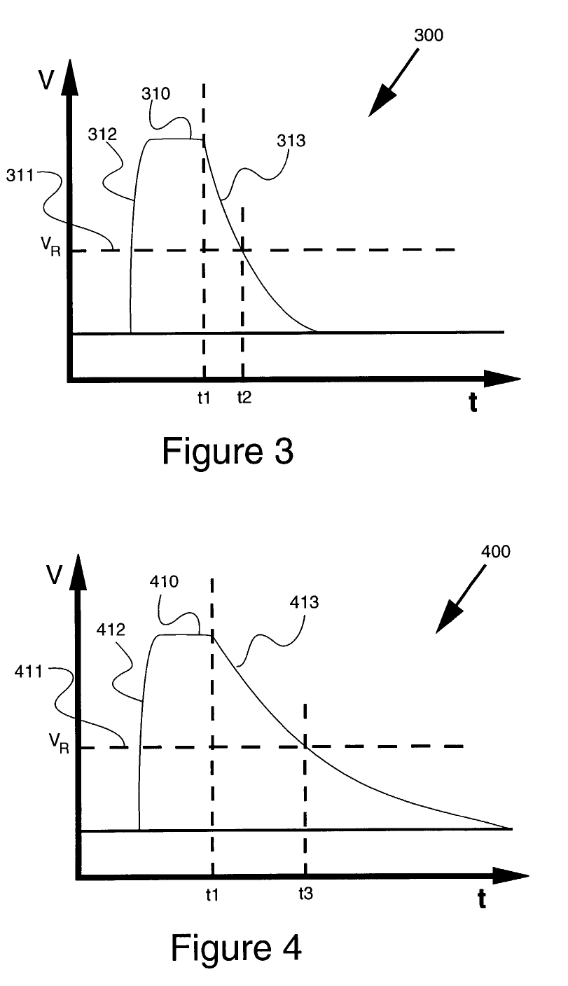

Attention is now directed to FIG. 3, which illustrates the waveform received by pin B2 during the measurement process. When pin C1 is set high, the voltage received by pin B2 is represented by the charge up curve 312 that level off at 310, the high voltage level of pin C1 subtracted by the voltage drop of the diode 212. At the moment t1, pin C1 and A3 are set low and the capacitor 242 starts to discharge through the external resistor 220. When the discharging voltage drops to a threshold level 311, the logic level received by pin B2 changes from logic high to logic low and the time t2 is recorded. The timing between t2 and t1 represents the resistance value of the external resistor 220. FIG. 4 represents the discharge curve when the resistor 220 is of a higher resistance value. The discharge curve 413 takes a longer time to reach the threshold level 411. The time in between t3 and t1 therefore reflects the higher resistance value of the resistor 220 and directs the microcontroller to provide another response according to the program directing the microcontroller. It should be noted that the programs that controls the measurement process, directing the table look up process to provide the responses and the data that represents the sound generated by the speaker 204 of FIG. 2 can be stored in different kinds of memory devices, either embedded inside the microcontroller 200 or located outside the microcontroller 200.

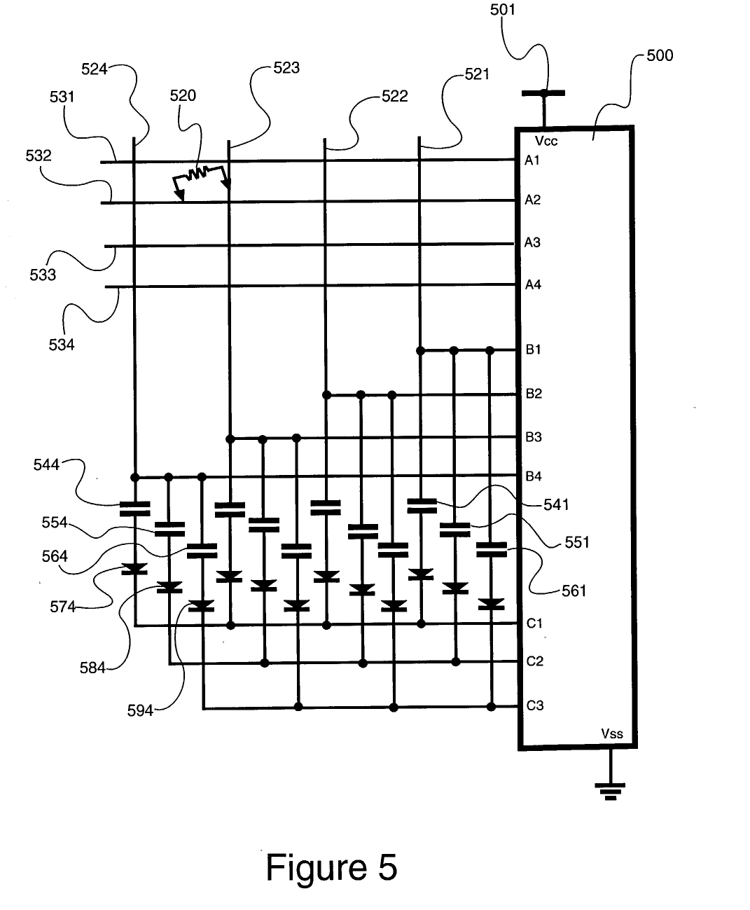

FIG. 5 illustrates an improvement of the electronics circuit shown in FIG. 2. Each column pin is connected to more than one capacitors, each of different value to handle external resistors of different resistance ranges. For example, the capacitor 541 is 470 uF which is suitable to work with the low resistance range from 100 ohm to 1 kohm. Capacitor 551 can be selected around 4.7 uF for it to work with resistance range of 1 kohm to 10 kohm. Capacitor 561 can be of a further lower value for it to work with higher resistance ranges. Tantalum capacitors are preferred choice for the low micro farad range due to the smaller size and good stability. Electrolytic capacitors are more commonly available for the higher micro farad range. For capacitance below 0.2 uF, ceramic capacitors can be selected. There are other different kinds of monolithic, mylar and film capacitors, each offer good performance at different capacitance ranges. Because of the wide range of resistance ranges to be serviced, capacitors made with different material or process are required to be connected with the same column pin for servicing different resistance ranges. The microcontroller 500 provides a third group of I/O pins C1 to C3 to determine which discharging capacitor is to be connected with the receivers. Diodes 574, 584 and 594 are connected in series to each capacitor so that the reference capacitors 541 to 564 will not be bridged by multiple resistors connected at different locations of the receiver matrix represented by the columns 521 to 524 and rows 531 to 534. If the I/O pins B1 to B4 are programmable I/O lines, the charging process can be provided by first settling the corresponding B1 to B4 line to output mode with high logic to charge up the reference capacitor and then return the line to high impedance input mode to monitor the discharge curve. In the embodiment of FIG. 5, after power up initialization, the pins A1 to A4 can be configured at logic high level. The pins B1 to B4 are configured as input pins that normally stay at a logic low pull down level. Interrupt function is provided to each of the B1 to B4 pins. Pins C1 to C3 are configured to stay at a high impedance mode. The chip is now in a low standby current mode ready to receive external resistors. When a resistor is connected to a receiver across one of the row pins and one of the column pins, the interrupt function wakes up the microcontroller into a higher current active mode. The row and column pins then perform a scanning routine by pulsing the A1 to A4 lines and reading the B1 to B4 lines to identify which pair of pins had been accessed. When the location of the external resistor is identified, the corresponding C1 to C3 lines is turned to low level for performing the charging and discharging measurement function.

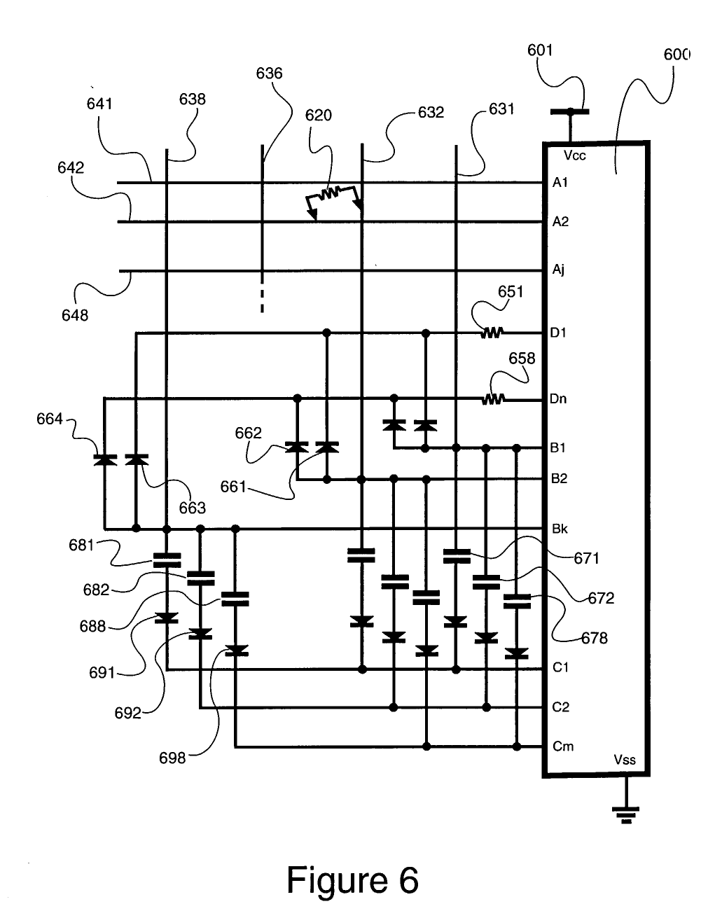

Many capacitors are not perfect for timing control applications. Electrolytic capacitors deteriorate overtime. Internal impedance, leakage current and capacitance may change after aging or repeated use. Many other capacitors change in capacitance values when the temperature of the working environment changes. Accordingly it is desirable to provide a calibration circuit before the actual measurement process is performed. FIG. 6 illustrates an example of the calibration circuit. High precision resistors 651 to 658 are connected to the column circuit to perform controlled discharging of the reference capacitors 671 to 688. The variation of each capacitor 671 to 688 is then taken into account and a compensation factor is provided for each capacitors before the resistance of the external resistor 620 is measured. The tolerance of the reference resistors 651 to 658 are preferred to be of higher tolerance, say 1%, to achieve better calibration result.

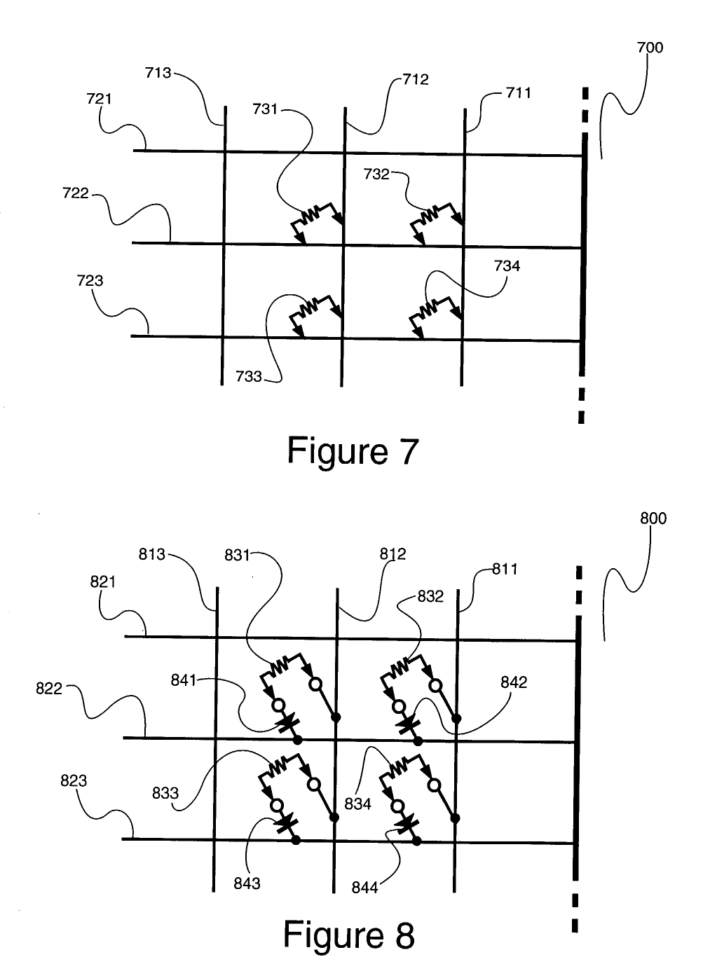

FIG. 7 provides an environment when multiple external resistors are connected to the receiver matrix. Assuming resistors 732, 733 and 734 are the external resistors previous received and stayed connected with the receivers shown, it can be observed that when the external resistor 731 is connected with the receiver defined by column 712 and row 722, the actual resistance measured between the receiver of 731 equals to the resistance value of 731 in parallel to another resistor equivalent to 732 to 734 connected in series. To prevent this effect, a diode is connected to each receiver as illustrated in FIG. 8. Assuming the current flows through the resistor 831 is flowing from the line 812 to the line 822, the current path flowing through resistors 833, 834 then to 832 is blocked by the reverse polarity of the diode 844. Accordingly proper measurement of the resistor 831 will not be affected by the pre-existence of the resistors 832, 833 and 834.

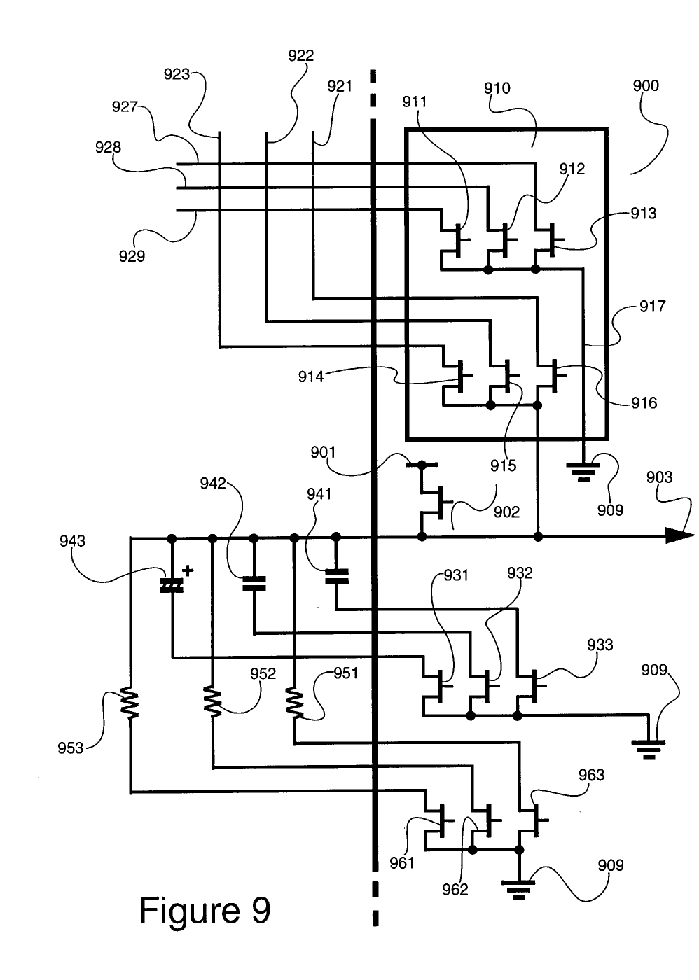

Attention is now direct to FIG. 9, which illustrates a simplified circuit of FIG. 6 which make use of a generic microcontroller 600. This circuit requires a custom made microcontroller IC 900. Only one array of reference capacitors 941 to 943, each of different value, and probably of different materials are required to be shared by all the receivers. The gates 931 to 933 select one of the capacitors 941 to 943 for performing the measurement function. The gate 901 charges up one of the capacitors 941 to 943 selected. The gates 961 to 963 then select the corresponding reference resistor 951 to 953 and perform a calibration procedure. Then the gate 901 is turned on again to recharge the selected capacitor. Gates 911 to 913 and 914 to 916 determine which receiver is to be measured. The discharge voltage is monitored by a sensing circuit receiving the discharge signal from the path 903. The teaching of FIG. 9 is directed to multiple resistance measurement circuit to be shared by all the members of the receiver matrix. Although only discharge capacitors of different nature is illustrated in FIG. 9, the same principle can be applied to other different kinds of resistance measurement circuits such as A/D converters or successive switch and compare circuits whereby multiple measurement circuits are shared by a matrix of receivers.

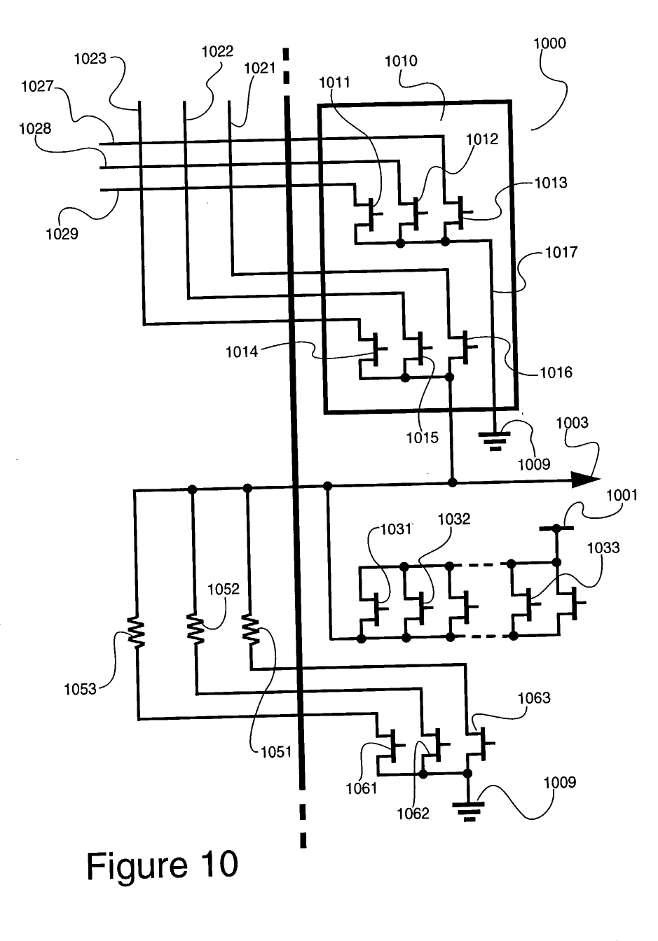

FIG. 10 illustrates modification of the electronics circuit of FIG. 9 by replacing the RC discharge circuit with the successive switch and compare IC design disclosed in the parent patent application of the subject invention. The RC discharge circuit of FIG. 9 is replaced by one or more arrays of switched resistors represented by the gates 1031 to 1033. Each element of these gates, when turned on, provide a different resistance connected in series the selected receiver through the switching gates 1011 to 1016. The voltage obtained from the path 1003 depends on the values of the external resistor under measurement and the resistance of the gate 1031 to 1033 selected. Successively switching the gated resistors 1031 to 1033 changes the voltage 1003 until it hits the threshold level. Successive approximation technique well known in the art can be used to quickly adjusting the voltage divider to get close to the threshold level. Because precision resistances of the gates 1031 to 1033 may be difficult due to variation of IC fabrication process, external reference resistors 1051 to 1053 and selection gates 1061 to 1063 are provided for performing the calibration process as previously discussed. It should be noted that the voltage at path 1003 can be fed to an A/D converter instead of using a successive approximation approach.

From the foregoing, it should now be appreciated that the applicant has disclosed herein embodiments of an electronics circuit designed for a matrix array of receivers configured to detect multiple high resolution external resistors selected from the 100 ohm to 1 Mohm range, and to provide different responses according to the resistance of a resistor connected to a receiver. Particularly, it should be noted that there are different variations of contact designs, different ways to measure resistor values and different arrangements to calibrate the measurement circuits. It should also be noted that the different unique features of the illustrated embodiment can be enhanced, reduced or simplified to meet the different application needs, which are not limited to toy applications. Although detailed embodiments of the invention have been disclosed, it is recognized that variations and modifications, all within the spirit of the invention, will occur to those skilled in the art. It is accordingly intended that all such variations and modifications be encompassed by the appended claims.

What is claimed is:

1. An electronics circuit providing an array of receivers to identify the resistance values of external resistors, said electronics circuit comprising:
a microcontroller having a first group of m interface pins and a second group of n interface pins;
first group of n capacitors each connected to one of said n interface pins;
at least first and second receivers each comprises a first contact point and a second contact point for receiving an external resistor; wherein said first contact point is connected to one of said first group of interface pins and said second contact point is connected to one of said second group of interface pins; and
a software resided in memory means enabling said microcontroller to identify the resistance of an external resistor received by any of said receivers according to the charging or discharging characteristics of said capacitor in conjunction with said external resistor.

2. The electronics circuit of claim 1 wherein each of said n interface pins is connected by a diode to a current source for charging up said n capacitors.

3. The electronics circuit of claim 1 wherein said n interface pins are programmable, and said n interface pins are programmed to provide an output mode for charging or discharging said n capacitors.

4. The electronics circuit of claim 1 wherein said n interface pins are programmed to provide an input mode to monitor the charging or discharging timing of said n capacitors.

5. The electronics circuit of claim 1 wherein said m interface pins are programmed to provide an input mode to detect the presence of an external resistor.

6. The electronics circuit of claim 1 wherein said m interface pins are programmed to provide an output mode for charging or discharging said n capacitors.

7. The electronics circuit of claim 1 wherein said microprocessor is in a low current standby mode before a resistor is received by a receiver of said electronics circuit, and said microprocessor is transformed from said standby mode into a higher current active mode when an external resistor is received by one of said receivers.

8. The electronics circuit of claim 1 wherein each of said n capacitors is connected in series with a diode.

9. The electronics circuit of claim 1 wherein each of said n pins are further connected with a second group of n capacitors and each of said second group of capacitors is of capacitance value different from that of the first group of capacitors.

10. The electronics circuit of claim 9 wherein said first group of capacitors are activated to identify the value of an external resistor within a first resistance range, and said second group of capacitors are activated to identify the value of an external resistor within a second resistance range.

11. The electronics circuit of claim 1 wherein each of said n interface pins is connected with a reference resistor for calibrating the charging or discharging characteristics of said capacitors.

12. The electronics circuit of claim 11 wherein each of said reference resistor is connected in series with a diode.

13. The electronics circuit of claim 1 wherein said microcontroller provides different responses according to different resistor value received by said receivers.

14. The electronics circuit of claim 1 wherein a first external resistor is received by said first receiver, and said microcontroller provides a response when a second external resistor is received by said second receiver.

15. An electronics circuit configured to identify the resistance values of external resistors comprising:
a microcontroller having a first group of m interface pins and a second group of n interface pins;
at least first and second receivers each comprises a first contact point connect to one of the m pins and a second contact point connected to one of the n pins for receiving an external resistor; said electronics circuit further comprising at lease one of the following members:
(a) a first array of capacitors each connected to one of said n interface pins;
(b) a first array of capacitors each connected to one of said n interface pins and a second array of capacitors each connected to one of said n interface pins;
(c) a first array of capacitors each connected to one of said n interface pins and an array of reference resistors configured to calibrate the charging or discharging characteristic of said first array of capacitors;
(d) a first array of capacitors each connected to one of said n interface pins; a second array of capacitors each connected to one of said n interface pins; a first array of reference resistors configured to calibrate the charging or discharging characteristic of said first array of capacitors and a second array of reference resistors configured to calibrate the charging or discharging characteristics of said second array of capacitors;
(e) a first array of capacitors each connected to one of said n interface pins; a second array of capacitors each connected to one of said n interface pins and a third group of k interface pins configured to activate one of said first or second arrays of capacitors;
(f) a first array of capacitors each connected to one of said n interface pins; a second array of capacitors each connected to one of said n interface pins; a first array of reference resistors configured to calibrate the charging or discharging characteristic of said first array of capacitors; a second array of reference resistors configured to calibrate the charging or discharging characteristics of said second array of capacitors and a third group of interface pins to activate one of said first or second arrays of reference resistors;
(g) an array of internal resistance elements located inside said microcontroller for connecting in series or in parallel with said external resistor;
(h) an array of internal resistance elements located inside said microcontroller for connecting in series or in parallel with a receiver for identifying the resistance value of a resistor received by said receiver;
(i) first and second capacitors of different capacitance values and switching circuit connecting any of said first or second capacitors to a receiver for identifying the resistance value of an external resistor received by said receiver; and
(j) first and second capacitors each made with different materials and switching circuit connecting any of said first or second capacitors to a receiver for identifying the resistance value of an external resistor received by said receiver.

16. The electronics circuit of claim 15 further comprising a diode connected in series with any of the following members:
(i) said first and second receivers;
(ii) the capacitors of member (b), (c), (d), (e), (f), (i) or (j); and
(iii) the reference resistors of member (c), (d) or (f).

17. A method for an electronics circuit to provide response according to the resistance identity of an external resistor, wherein said electronics circuit comprises:
a microcontroller having a first group of m interface pins and a second group of n interface pins;
at least first and second receivers each comprises a first contact point and a second contact point configured for receiving an external resistor; wherein said first contact point is connected to one of said first group of interface pins and said second contact point is connected to one of said second group of interface pins;
first group of n capacitors each connected to one of said n interface pins; and
a software resided in memory means enabling said microcontroller to determine the resistance of an external resistor received by any of said receivers according to the charging or discharging characteristics of said capacitor in conjunction with said external resistor;
said method comprises the steps of:
(1) arranging said electronics circuit to stay at a low power standby mode;
(2) arranging a first external article identified by a first resistor to make contact with said first receiver;
(3) arranging said electronics circuit to transform from the standby mode into an active mode;
(4) charging or discharging a capacitor connected with said first resistor to determine the identity of said first resistor; and
(5) providing a response according to the identity of said first resistor detected.

18. The method of claim 17 further comprising the step of:
(6) while said first resistor remains in contact with said first receiver, arranging a second external article identified by a second resistor to make contact with said second receiver;
(7) charging or discharging a capacitor connected with said second resistor to determine the identity of said second resistor; and
(8) providing a response according to the identity of said second resistor detected.

19. An electronics circuit providing an array of receivers to identify the resistance values of external resistors, said electronics circuit comprising:
a microcontroller having a first group of m interface pins and a second group of n interface pins;
at least first and second receivers each comprises a first contact point and a second contact point for receiving an external resistor; wherein said first contact point is connected to one of said first group of interface pins and said second contact point is connected to one of said second group of interface pins;
first and second resistor identifying circuits each configured to detect resistors of different resistance ranges;
switching circuit configured to connect one of said resistor identifying circuit to an external resistor when it is received by one of said receivers; and
a software resided in memory means configured for said microcontroller to control said switching circuit and identify the resistance of said external resistor received.

20. The electronics circuit of claim 19 wherein each of said resistor identifying circuits is configured to identify an external resistor by charging or discharging a capacitor by said external resistor.

21. The electronics circuit of claim 20 wherein the capacitor of each resistor identifying circuit is of different value to service different resistance range of the external resistors received.

22. The electronics circuit of claim 20 wherein the capacitor of each resistor identifying circuit is made with different material to service different resistance range of the external resistors received.

23. The electronics circuit of claim 19 wherein said resistor identifying circuits comprise an array of resistors and a switching circuit connecting said external resistor in series or parallel to a member of said array of resistors.
